(19) United States
(12) Patent Application Publication
(10) Pub. No.: US 2006/0093069 A1
(43) Pub. Date: May 4, 2006

(54) Method and system for sharing GM stage for a second if mixer using a polyphase clock to reduce current consumption and improve matching

(76) Inventor: Meng-An (Michael) Pan, Irvine, CA (US)

Correspondence Address: MCANDREWS HELD & MALLOY, LTD, 500 WEST MADISON STREET, SUITE 3400, CHICAGO, IL, 60661, US

(21) Appl. No.: 10/977,210

(22) Filed: Oct. 29, 2004

(51) Int. Cl. H03D 3/00

(52) U.S. Cl. 375/322

(57) ABSTRACT

A method for improving signal quality in a receiver is provided. The method may comprise generating a plurality of output signals from a single I component Gm stage and a single Q component Gm stage. The generated plurality of output signals may be mirrored from said I component Gm stage to a first I component mixer circuit and a second I component mixer circuit, and from the Q component Gm stage to a first Q component mixer circuit and a second Q component mixer circuit. An output DC signal may be generated from an output of the first I component mixer circuit and the first Q component mixer circuit. An output may be generated that may comprise a difference signal from the second I component mixer circuit and the second Q component mixer circuit.

### CROSS-REFERENCE TO RELATED APPLICATIONS/INCORPORATION BY REFERENCE

This application is related to the following applications, each of which is incorporated herein by reference in its entirety for all purposes:

U.S. patent application Ser. No. ______ (Attorney Docket No. 16149US01) filed ______, 2004;

U.S. patent application Ser. No. ______ (Attorney Docket No. 16150US01) filed ______, 2004;

U.S. patent application Ser. No. ______ (Attorney Docket No. US01) filed ______, 2004;

U.S. patent application Ser. No. ______ (Attorney Docket No. 16152US01) filed ______, 2004;

U.S. patent application Ser. No. ______ (Attorney Docket No. 16153US01) filed ______, 2004;

U.S. patent application Ser. No. ______ (Attorney Docket No. 16154US01) filed ______, 2004;

U.S. patent application Ser. No. ______ (Attorney Docket No. 16155US01) filed ______, 2004;

U.S. patent application Ser. No. ______ (Attorney Docket No. 16156US01) filed ______, 2004;

U.S. patent application Ser. No. ______ (Attorney Docket No. 16157US01) filed ______, 2004;

U.S. patent application Ser. No. ______ (Attorney Docket No. 16158US01) filed ______, 2004;

U.S. patent application Ser. No. ______ (Attorney Docket No. 16162US01) filed ______, 2004;

U.S. patent application Ser. No. ______ (Attorney Docket No. 16228US01) filed ______, 2004;

U.S. patent application Ser. No. ______ (Attorney Docket No. 16230US01) filed ______, 2004;

U.S. patent application Ser. No. ______ (Attorney Docket No. 16234US01) filed ______, 2004;

U.S. patent application Ser. No. ______ (Attorney Docket No. 16236US01) filed ______, 2004; and

U.S. patent application Ser. No. ______ (Attorney Docket No. 16237US01) filed ______, 2004.

### FIELD OF THE INVENTION

Certain embodiments of the invention relate to processing of radio signals in a radio frequency (RF) transceiver. More specifically, certain embodiments of the invention relate to a method and system for sharing Gm stage for a second IF mixer using a polyphase clock to reduce current consumption and improve matching.

### BACKGROUND OF THE INVENTION

In some conventional systems, a radio frequency (RF) signal may be converted to an intermediate frequency (IF), and then from IF to a baseband signal, where the IF may be in the megahertz range. Generally, the RF signal may be mixed with a local oscillator signal that may result in two sideband signals that may be the sum of the frequencies of the two signals and the difference of the frequencies of the two signals. One of the two sideband signals may be chosen as an IF signal, and this IF signal may be the same for all received RF signals. A radio that may receive a plurality of channels, such as an AM or FM radio, may tune to a particular station by changing the local oscillator signal frequency such that the IF remains constant. With a constant IF, most of the receive path may be common in the receiver.

Today, much of radio receiver development may be driven mostly by a great demand for mobile wireless communication devices, including handsets. With the ever-decreasing size of mobile handsets, capacities of smaller batteries may be an issue. As most of these handsets may use complementary metal-oxide semiconductor (CMOS) technology for analog to digital conversion, and for much of the processing of voice and data signals, a very important factor to consider may be that it may be advantageous for CMOS devices to work at lower frequencies. This may be crucial since CMOS devices have power dissipation directly related to the speed at which the CMOS devices switch. The faster the frequencies, the faster the CMOS device switching speed, and therefore, the greater the amount of power consumed. The receivers may be designed to downconvert the high frequency RF, which may be in gigahertz range, to a lower frequency, preferably to a baseband frequency, as quickly as possible.

As a result, some receivers may utilize chips for digitally processing baseband signals, and may expect to receive the baseband signal, rather than an IF signal. To meet this need, some receiver architectures, for example, direct-conversion receivers, try to do away with IF by converting directly from RF to baseband, and therefore reduce power consumption by not processing IF signals, and cost by not having to deal with IF signals. However, with direct conversion, the reduced power consumption may be offset by strong drawbacks, such as DC-offset generation, interference noise, I/Q mismatch, excessive flicker noise in the baseband, and local oscillator (LO) leakage. In addition, a digital signal processor (DSP) may be required to perform complex digital processing of the digital signal for filtering and downconverting from the RF frequency.

If a measured signal-to-noise ratio (SNR) is less than a desired SNR, the DSP may need to perform, for example, distortion cancellation or other SNR reduction or mitigation function. Additionally, during direct conversion a majority of gain and filtering may be performed in a frequency band from DC to the signal bandwidth. In this process, a signal path's intrinsic DC offsets may be amplified. The dynamic range of the circuit may thereby be degraded. In addition, a DC offset may be created if the LO signal leaks to the RF front end and self-mixes. Some systems, for example, GSM systems, may use modulation and system synchronization techniques that require DC information, therefore, it may not be feasible to simply remove the DC component and complex DSP processing may be required to reduce the DC offset while still keeping the information present in the DC signal.

Although direct conversion receivers may try to reduce parts count and try to reduce power consumption, additional complex digital signal processing, and its accompanying cost, may be required. Furthermore, the digital baseband signal may have to be converted to an analog signal for some baseband processors.

Further limitations and disadvantages of conventional and traditional approaches will become apparent to one of skill in the art, through comparison of such systems with some aspects of the present invention as set forth in the remainder of the present application with reference to the drawings.

### BRIEF SUMMARY OF THE INVENTION

Certain embodiments of the invention may be found in a method and system for sharing Gm stage for a second IF mixer using a polyphase clock to reduce current consumption and improve matching. A method for improving signal quality in a receiver may be provided. The method may comprise generating a plurality of output signals from a single I component Gm stage and a single Q component Gm stage. The generated plurality of output signals may be mirrored from said I component Gm stage to a first I component mixer circuit and a second I component mixer circuit, and from the Q component Gm stage to a first Q component mixer circuit and a second Q component mixer circuit. An output DC signal may be generated from an output of the first I component mixer circuit and the first Q component mixer circuit. An output may be generated that may comprise a difference signal from the second I component mixer circuit and the second Q component mixer circuit.

The generated plurality of output signals mirrored from the I component Gm stage to the first I component mixer circuit may be defined by cos(2πf_{if}t), where f_{if} may be a base frequency of the generated plurality of output signals from the I component Gm stage to the first I component mixer circuit. A first signal may be generated by mixing the generated plurality of output signals mirrored from the I component Gm stage to the first I component mixer circuit with a local oscillator I component signal that may be defined by cos(2πfₗₒt), where fₗₒ may be a frequency of the local oscillator I component signal. The generated plurality of output signals mirrored from the Q component Gm stage to the first Q component mixer circuit may be defined by sin(2πf_{if}t), where f_{if} may be a base frequency of the generated plurality of output signals mirrored from the Q component Gm stage to the first Q component mixer circuit. A second signal may be generated by mixing the generated plurality of output signals mirrored from the Q component Gm stage to the first Q component mixer circuit with a local oscillator Q component signal that may be defined by sin(2πfₗₒt), where fₗₒ may be a frequency of the local oscillator Q component signal. The generated first signal and the generated second signal may be added to generate the output DC signal.

The generated plurality of output signals mirrored from the I component Gm stage to the second I component mixer circuit may be defined by cos(2πf_{if}t), where f_{if} may be a base frequency of the generated plurality of output signals from the I component Gm stage to the second I component mixer circuit. A third signal may be generated by mixing the generated plurality of output signals mirrored from the I component Gm stage to the second I component mixer circuit with a local oscillator Q component signal that may be defined by sin(2πfₗₒt), where fₗₒ may be a frequency of the local oscillator Q component signal. The generated plurality of output signals mirrored from the Q component Gm stage to the second Q component mixer circuit may be defined by sin(2πf_{if}t), where f_{if} may be a base frequency of the generated plurality of output signals mirrored from the Q component Gm stage to the second Q component mixer circuit. A fourth signal may be generated by mixing the generated plurality of output signals mirrored from the Q component Gm stage to the second Q component mixer circuit with a local oscillator I component signal that may be defined by cos(2πfₗₒt), where fₗₒ may be a frequency of the local oscillator I component signal. The generated third signal and the generated fourth signal may be added to generate the output that may comprise the difference signal.

Another embodiment of the invention may provide a machine-readable storage, having stored thereon, a computer program having at least one code section executable by a machine, thereby causing the machine to perform the steps as described above for sharing Gm stage for a second IF mixer using a polyphase clock to reduce current consumption and improve matching.

In accordance with an embodiment of the invention, a system for improving signal quality in a receiver may be provided. The system may comprise circuitry that may be adapted to generate a plurality of output signals from a single I component Gm stage and a single Q component Gm stage. Circuitry may be adapted to mirror the generated plurality of output signals from said I component Gm stage to a first I component mixer circuit and a second I component mixer circuit, and from the Q component Gm stage to a first Q component mixer circuit and a second Q component mixer circuit. The system may comprise circuitry that may be adapted to generate an output DC signal from an output of the first I component mixer circuit and the first Q component mixer circuit. Circuitry may be adapted to generate an output that may comprise a difference signal from the second I component mixer circuit and the second Q component mixer circuit.

The generated plurality of output signals mirrored from the I component Gm stage to the first I component mixer circuit may be defined by cos(2πf_{if}t), where f_{if} may be a base frequency of the generated plurality of output signals from the I component Gm stage to the first I component mixer circuit. The system may comprise circuitry that may be adapted to generate a first signal by mixing the generated plurality of output signals mirrored from the I component Gm stage to the first I component mixer circuit with a local oscillator I component signal that may be defined by cos(2πfₗₒt), where fₗₒ may be a frequency of the local oscillator I component signal. The generated plurality of output signals mirrored from the Q component Gm stage to the first Q component mixer circuit may be defined by sin(2πf_{if}t), where f_{if} may be a base frequency of the generated plurality of output signals mirrored from the Q component Gm stage to the first Q component mixer circuit. The system may comprise circuitry that may be adapted to generate a second signal by mixing the generated plurality of output signals mirrored from the Q component Gm stage to the first Q component mixer circuit with a local oscillator Q component signal that may be defined by sin(2πfₗₒt), where fₗₒ may be a frequency of the local oscillator Q component signal. Circuitry may be adapted to add the generated first signal and the generated second signal to generate the output DC signal.

The generated plurality of output signals mirrored from the I component Gm stage to the second I component mixer circuit may be defined by cos(2πf_{if}t), where f_{if} may be a base frequency of the generated plurality of output signals from the I component Gm stage to the second I component mixer circuit. The system may comprise circuitry that may be adapted to generate a third signal by mixing the generated plurality of output signals mirrored from the I component Gm stage to the second I component mixer circuit with a local oscillator Q component signal that may be defined by sin(2πfₗₒt), where fₗₒ may be a frequency of the local oscillator Q component signal. The generated plurality of output signals mirrored from the Q component Gm stage to the second Q component mixer circuit may be defined by sin(2πf_{if}t), where f_{if} may be a base frequency of the generated plurality of output signals mirrored from the Q component Gm stage to the second Q component mixer circuit. The system may comprise circuitry that may be adapted to generate a fourth signal by mixing the generated plurality of output signals mirrored from the Q component Gm stage to the second Q component mixer circuit with a local oscillator I component signal that may be defined by cos(2πfₗₒt), where fₗₒ may be a frequency of the local oscillator I component signal. Circuitry may be adapted to add the generated third signal and the generated fourth signal to generate the output that may comprise the difference signal.

These and other advantages, aspects and novel features of the present invention, as well as details of an illustrated embodiment thereof, will be more fully understood from the following description and drawings.

### BRIEF DESCRIPTION OF SEVERAL VIEWS OF THE DRAWINGS

FIG. 1A is a block diagram of an exemplary radio frequency RF transceiver system, in accordance with an embodiment of the invention.

FIG. 1B is a block diagram of a receiver portion of a RF transceiver front end with dual mode mixers, in accordance with an embodiment of the invention.

FIG. 1C illustrates an exemplary baseband down conversion operation in a dual mode mixer, in accordance with an embodiment of the invention.

FIG. 1D is a circuit diagram of an exemplary dual mode mixer in baseband down conversion configuration, in accordance with an embodiment of the invention.

FIG. 1E is a block diagram illustrating an exemplary single sideband mixing circuit, in accordance with an embodiment of the invention.

FIG. 1F is a block diagram illustrating an alternate exemplary single sideband mixing circuit, in accordance with an embodiment of the invention.

FIG. 1G is a timing diagram illustrating exemplary local oscillator signals out of phase by 90° with each other, in accordance with an embodiment of the invention.

FIG. 2 is a block diagram of a receiver portion illustrating a plurality of single sideband mixing circuits, in accordance with an embodiment of the invention.

FIG. 3 is a circuit diagram of an exemplary I component Gm stage, in accordance with an embodiment of the invention.

FIG. 4 is a circuit diagram of an exemplary I component mixer circuit, in accordance with an embodiment of the invention.

FIG. 5 is a flowchart illustrating exemplary steps to generate a differential output DC signal, in accordance with an embodiment of the invention.

### DETAILED DESCRIPTION OF THE INVENTION

Certain embodiments of the invention may be found in a method and system for sharing Gm stage for a second IF mixer using a polyphase clock to reduce current consumption and improve matching. A method for improving signal quality in a receiver may be provided. The method may comprise generating a plurality of output signals from a single I component Gm stage and a single Q component Gm stage. The generated plurality of output signals may be mirrored from said I component Gm stage to a first I component mixer circuit and a second I component mixer circuit, and from the Q component Gm stage to a first Q component mixer circuit and a second Q component mixer circuit. An output DC signal may be generated from an output of the first I component mixer circuit and the first Q component mixer circuit. An output may be generated that may comprise a difference signal from the second I component mixer circuit and the second Q component mixer circuit. Accordingly, this eliminates utilizing a plurality of Gm stages, thereby reducing cost, power consumption and chip size.

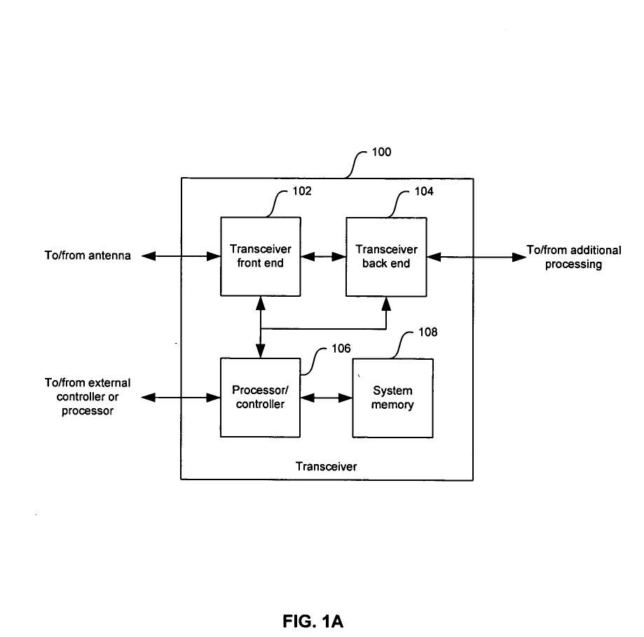

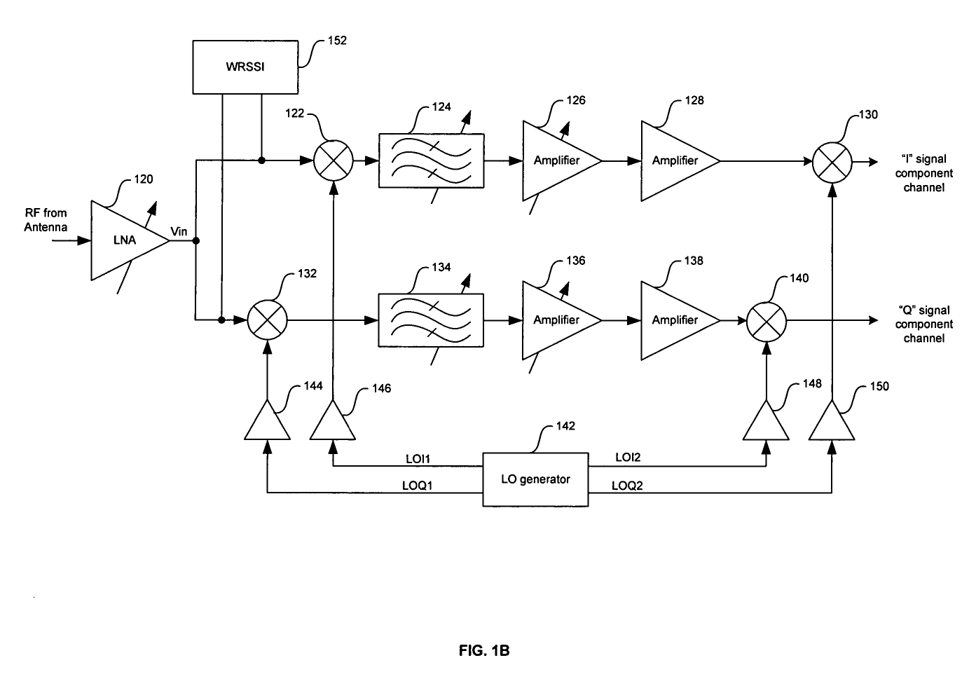

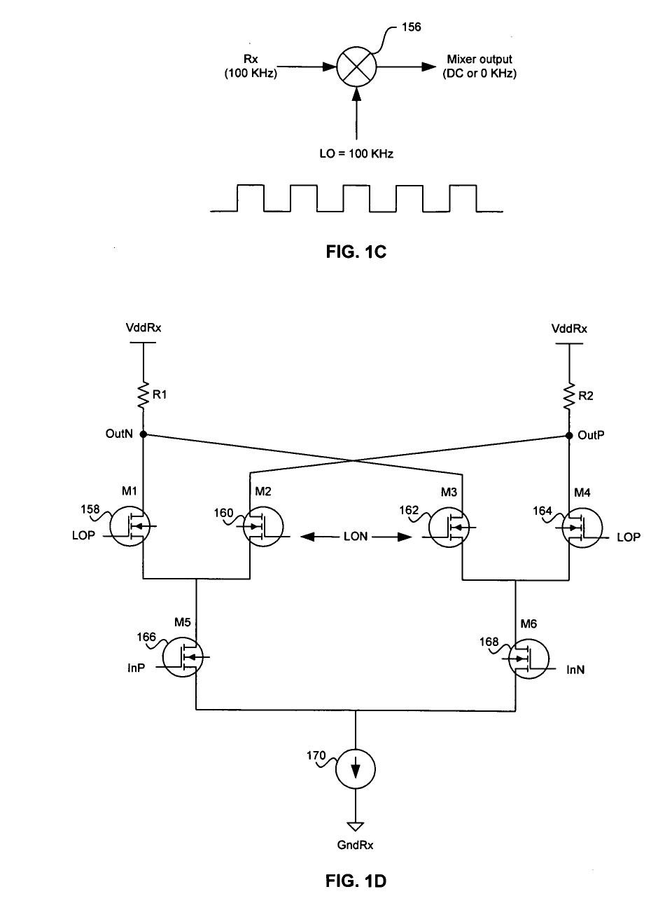

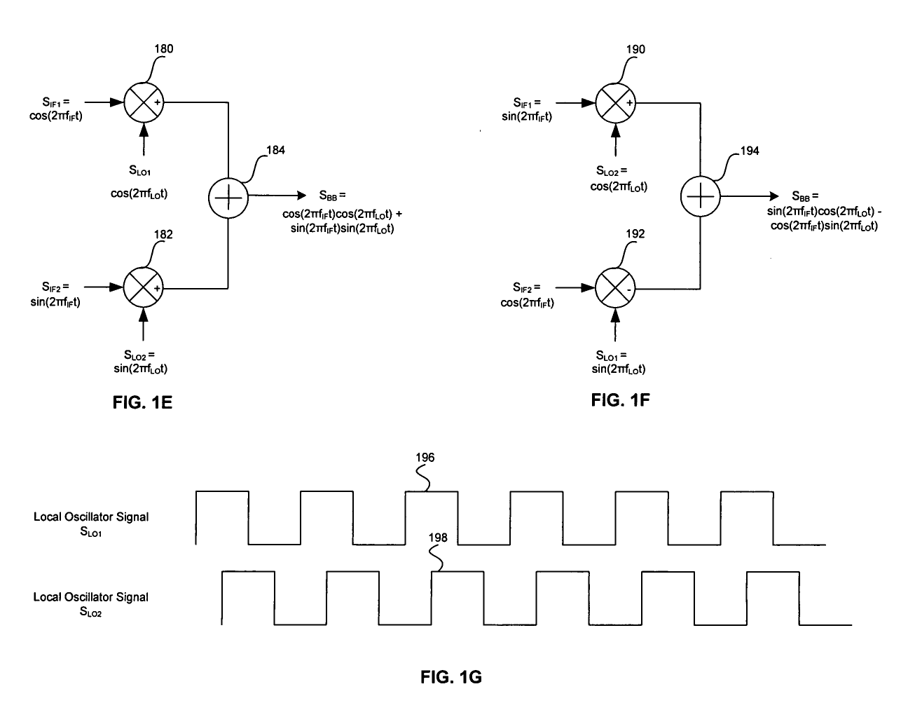

FIG. 1A is a block diagram of an exemplary RF transceiver system, in accordance with an embodiment of the invention. Referring to FIG. 1A, the RF transceiver system 100 may comprise a transceiver front end 102, a transceiver back end 104, a controller/processor 106, and a system memory 108. The transceiver front end 102 may comprise suitable logic, circuitry, and/or code that may be adapted to receive and/or transmit an RF signal. The transceiver front end 102 may comprise a receiver portion and a transmitter portion. Both the transmitter portion and the receiver portion may be coupled to an external antenna for signal broadcasting and signal reception respectively. The transceiver front end 102 may modulate a signal for transmission and may also demodulate a received signal before further processing of the received signal occurs. Moreover, the transceiver front end 102 may provide other functions, for example, digital-to-analog conversion, analog-to-digital conversion, frequency downsampling, frequency upsampling, and/or filtering. The transceiver front end 102 may provide a local oscillator frequency, which may be utilized for modulation and/or demodulation operations.

The transceiver back end 104 may comprise suitable logic, circuitry, and/or code that may be adapted to digitally process received signals from the transceiver front end 102 and/or to process signals received from at least one processing block, which may be located external to the RF transceiver system 100. The transceiver back end 104 may comprise, for example, a baseband processor. In this case, signals transferred from the transceiver front end 102 to the transceiver back end 104 may have been downconverted to a baseband frequency. The transceiver back end 104 may also comprise a signal interface that allows the transceiver front end 102 to transfer signals that have been downconverted to a low IF. In this case, a baseband processor in the transceiver back end 104 may process information after downconversion to the baseband frequency by the signal interface.

The controller/processor 106 may comprise suitable logic, circuitry, and/or code that may be adapted to control the operations of the transceiver front end 102 and/or the transceiver back end 104. For example, the controller/processor 106 may be utilized to update and/or modify programmable parameters and/or values in a plurality of components, devices, and/or processing elements in the transceiver front end 102 and/or in the transceiver back end 104. Control and/or data information may be transferred from at least one controller and/or processor external to the RF transceiver system 100 to the controller/processor 106 during the operation of the RF transceiver system 100. Moreover, the controller/processor 106 may also be adapted to transfer control and/or data information to at least one controller and/or processor external to the RF transceiver system 100.

The controller/processor 106 may be adapted to utilize the received control and/or data information to determine the mode of operation of the transceiver front end 102. For example, the controller/processor 106 may be adapted to select between a mode of operation where a received signal in the transceiver front end 102 may be down converted to a baseband frequency or a mode of operation where a received signal may be downconverted to a low IF. The system memory 108 may comprise suitable logic, circuitry, and/or code that may be adapted to store a plurality of control and/or data information.

FIG. 1B is a block diagram of a receiver portion of a RF transceiver front end with dual mode mixers, in accordance with an embodiment of the invention. Referring to FIG. 1B, there is shown a low noise amplifier (LNA) 120, mixers 122 and 132, bandpass filters 124 and 134, programmable gain amplifiers (PGA) 126 and 136, amplifiers 128 and 138, mixer blocks 130 and 140, a wideband receiver signal strength indicator (WRSSI) 152, buffers 144, 146, 148, and 150, and local oscillator (LO) generator 142. The LNA 120 may comprise suitable logic, circuitry, and/or code that may be adapted to amplify input signals and output the amplified signals. The LNA 120 may be utilized in instances where the signal to noise ratio (SNR) may be relatively low, such as, for example, RF signals received by an antenna. Certain aspects of the LNA 120 may be controllable and may be controlled by, for example, the processor/controller 106 in FIG. 1A. For example, the LNA 120 may be adapted to have a controllable gain. The WRSSI 152 may comprise suitable logic, circuitry, and/or code that may be adapted to determine the strength of the received signal. The WRSSI 152 may be adapted to generate a feedback control signal to the LNA 120 to modify the gain setting, for example.

The mixers 122 and 132 may comprise suitable logic, circuitry, and/or code that may be adapted to have as inputs two signals, and generate an output signal, which may be a difference of the frequencies of the two input signals and/or a sum of the frequencies of the two input signals. The mixers 122 and 132 may be adapted to down convert the received signal from an RF modulation frequency to an intermediate frequency (IF), for example. The mixers 122 and 132 may be adapted to utilize the local oscillator signals LOI1 and LOQ1, respectively. In this regard, the LOI1 and LOQ1 signals may comprise a plurality of signals.

The bandpass filters 124 and 134 may comprise suitable logic, circuitry, and/or code that may be adapted to selectively pass signals within a certain bandwidth while attenuating signals outside that bandwidth. The bandpass filters 124 and 134 may further comprise an amplifier circuit that may amplify the bandpass filtered signal, and the gain of the amplifier circuit may be controlled by, for example, the transceiver back end 104 or the processor/controller 106 in FIG. 1A.

The PGAs 126 and 136 may comprise suitable logic, circuitry, and/or code that may be adapted to amplify input signals and output the amplified signals. Certain aspects of the PGAs 126 and 136 may be controllable. The gain of the PGAs 126 and 136 may be controllable and may be controlled by, for example, the transceiver back end 104 or the processor/controller 106 in FIG. 1A. The gain of the PGAs 126 and 136 may be as high as, for example, 30 dB. The amplifiers 128 and 138 may comprise suitable logic, circuitry, and/or code that may be adapted to amplify input signals and output the amplified signals. The amplifiers 128 and 138 may be fixed gain amplifiers, and the gain may be fixed, for example, at 15 dB.

The mixer blocks 130 and 140 may comprise suitable logic, circuitry, and/or code that may be adapted to mix an input signal with a local oscillator input signal to produce an output signal that may be a difference of the frequencies of the two input signals and/or a sum of the frequencies of the two input signals. The mixer blocks 130 and 140 may be adapted to select between a low intermediate frequency (IF) mode or a baseband frequency mode. In this regard, the mixer blocks 130 and 140 may be said to be dual mode mixer blocks, for example. When the low intermediate frequency (IF) mode is selected, the mixer blocks 130 and 140 may pass through the input signal without performing a down conversion. When the baseband frequency mode is selected, the mixer blocks 130 and 140 may down convert the input signal to zero frequency or baseband at the output. Moreover, the mixer blocks 130 and 140 may reduce noise around a desired bandwidth of the output signal by utilizing phase shifted input signals and phase shifted local oscillator signals.

The local oscillator (LO) generator 142 may comprise suitable logic, circuitry, and/or code that may be adapted to generate local oscillator signals that may be utilized by the mixers 122 and 132 and the mixer blocks 130 and 140. In this regard, the LO generator 142 may generate a plurality of signals. While the LO generator 142 in FIG. 1B is shown to generate the signals LOI1, LOI2, LOQ1, and LOQ2, it may not be so limited. The LO generator 142 may generate local oscillator signals LOI1 and LOQ1 of a plurality of frequencies and/or at different phase values relative to each other. The LO generator 142 may generate local oscillator signals LOI2 and LOQ2 of a plurality of frequencies and/or at different phase values relative to each other. In this regard, the operation and output signals generated by the LO generator 142 may be controllable and may be controlled by, for example, the transceiver back end 104 or the processor/controller 106 in FIG. 1A. The buffers 144, 146, 148, and 150 may comprise suitable logic, circuitry, and/or code that may be adapted to buffer the local oscillator signals before being communicated or transferred to the corresponding frequency mixers.

In operation, the RF signal, which may have a carrier frequency referred to as ω₀, may be received by an antenna and communicated to the LNA 120, where the RF signal may be amplified by the LNA 120. The amplified RF signal may be communicated to an input of the mixers 122 and 132. The mixers 122 and 132 may mix this amplified signal with local oscillator signals LOI1 and LOQ1, respectively. The outputs of the mixers 122 and 132 may be intermediate frequency (IF) “I” and “Q” signal components, respectively. The intermediate frequency may be, for example, 100 KHz.

The IF “I” and “Q” signal components may be communicated to bandpass filters 124 and 134, which may be adapted to pass the desired bandwidth of signals about the IF frequency, while attenuating the undesired frequencies in the IF signal, and may also amplify the desired bandwidth of signals. The filtered and amplified IF “I” and “Q” signal components may be communicated to PGAs 126 and 136, and these signals may be amplified. The current gain of the PGAs 126 and 136 may be controlled by, for example, the transceiver back end 104 or the processor/controller 106 in FIG. 1A. The amplified output signals IF “I” and IF “Q” from the PGAs 126 and 136 may be communicated to the amplifiers 128 and 138. At the amplifiers 128 and 138, IF “I” and “Q” signal components may be further amplified. The IF “I” signal component at the output of the amplifier 128 may be communicated to at least the input of the mixer block 130 and the IF “Q” signal component at the output of the amplifier 138 may be communicated to at least the input of the mixer block 140.

The mixer blocks 130 and 140 may be configured to either pass through the IF “I” and “Q” signal components at the low IF or may be configured to down convert the IF “I” and “Q” signal components to “I” and “Q” baseband signals respectively. The local oscillator signals LOI2 and LOQ2 may be utilized as control signals to configure the operation of the mixer blocks 130 and 140. When the IF “I” and “Q” signal components are passed through, they may be transferred to a circuit, device, and/or component that comprises an IF interface. When the “I” and “Q” baseband signals are generated by down conversion at the mixer blocks 130 and 140, they may be transferred to a circuit, device, and/or component that comprises a baseband interface.

FIG. 1C illustrates an exemplary baseband down conversion operation in a dual mode mixer, in accordance with an embodiment of the invention. Referring to FIG. 1C, when the mode of operation selected is a baseband down conversion mode, a dual mode mixer block 156 may be utilized in a baseband down conversion configuration. The dual mode mixer block 156 may comprise suitable logic, circuitry, and/or code that may be adapted to generate a mixer output signal at baseband from an IF input signal and a IF local oscillator signal when the baseband down conversion mode is selected. In this case, the intermediate frequency may be 100 KHz, for example, and the baseband frequency refers to 0 KHz or DC frequency. The local oscillator frequency may be a differential signal and/or may be a square wave.

FIG. 1D is a circuit diagram of an exemplary dual mode mixer in baseband down conversion configuration, in accordance with an embodiment of the invention. Referring to FIG. 1D, the dual mode mixer block 156 in FIG. 1C may be implemented utilizing the exemplary circuit shown. The dual mode mixer block 156 may comprise a first NMOS transistor (M1) 158, a second NMOS transistor (M2) 160, a third NMOS transistor (M3) 162, a fourth NMOS transistor (M4) 164, a fifth NMOS transistor (M5) 166, a sixth NMOS transistor (M6) 168, resistors R1 and R2, and a current source 170. The implementation described in FIG. 1E may be referred to as a Gilbert cell.

Transistors M1 158, M2 160, M3 162, and M4 164 may be utilized to perform the frequency mixing operation in the dual mode mixer block 156. Transistors M5 166 and M6 168 may be utilized to provide a differential input gain based on the value of the current source 170. Resistors R1 and R2 may be utilized to provide load between the drains of the frequency mixing transistors and the supply voltage (VddRx).

In operation, when the mode of operation is the baseband down conversion mode, a positive signal of the local oscillator differential pair (LOP) may be applied to the gate of M1 158 and to the gate of M4 164, while a negative signal of the local oscillator differential pair (LON) may be applied to the gate of M2 160 and to the gate of M3 162. The positive signal of the IF signal component differential pair may be applied to the gate of M5 166 and the negative signal of the IF signal component differential pair may be applied to the gate of M6 168. In this configuration, the differential output generated at the nodes OutN and OutP may be a baseband frequency signal produced from the modulated IF differential pair and the IF local oscillator differential pair.

While the dual mode mixer block 156 as described in FIG. 1D comprises NMOS transistors and is implemented utilizing a single gain stage and a single mixing stage, the dual mode mixer block 156 may also be designed utilizing PMOS and/or CMOS devices and may also be implemented utilizing a plurality of gain and/or mixing stages.

FIG. 1E is a block diagram illustrating an exemplary single sideband mixing circuit, in accordance with an embodiment of the invention. Referring to FIG. 1E, there is shown two mixers 180 and 182 that may comprise suitable logic, circuitry and/or code that may be adapted mix two input signals and generate an output signal that may comprise frequencies that may be represented as a sum and a difference of frequencies of the two signals.

An IF signal S_{IF1} may be communicated to a first of the two inputs of the mixer 180, and a local oscillator (LO) signal S_{LO1} may be communicated to a second of the two inputs of the mixer 180. An IF signal S_{IF2} that may be 90° out of phase with the IF signal S_{IF1} may be communicated to a first of the two inputs of the mixer 182, and a local oscillator (LO) signal S_{LO2} that may be 90° out of phase with the local oscillator (LO) signal S_{LO1} may be communicated to a second of the two inputs of the mixer 182. The outputs of the mixers 180 and 182 may be coupled and added together by the adder block 184 to generate the output signal S_{BB}, in which an output baseband signal S_{BB} may be the desired component.

The IF signals S_{IF1} and S_{IF2} and the LO signals S_{LO1} and S_{LO2} may be represented by using sine and cosine notations to represent the two signals, and mixing the two signals may be represented by multiplying the two signals. Therefore, the IF signal S_{IF1} may be represented as
S_{IF1}=cos(2πf_{IF}t)
and since the IF signal S_{IF2} may be 90° (or π/2 radians) out of phase with the IF signal S_{IF1}, the IF signal may be represented as
S_{IF2}=cos(2πf_{IF}t−π/2)=sin(2πf_{IF}t).
Similarly, the LO signals S_{LO1} and S_{LO2} may be represented as
S_{LO1}=cos(2πf_{LO}t)
S_{LO2}=cos(2πf_{LO}t−π/2)=sin(2πf_{LO}t).
The output signals of the mixers 180 and 182 may then be represented as cos(2πf_{IF}t)cos(2πf_{LO}t) and sin(2πf_{IF}t)sin(2πf_{LO}t), respectively. Therefore, the output of the mixer 180 added to the output of the mixer 182 may be represented as
S_{BB}=cos(2πf_{IF}t)cos(2πf_{LO}t)+sin(2πf_{IF}t)sin(2πf_{LO}t)=cos(2π(f_{IF}−f_{LO})t)

The IF signals S_{IF1} and S_{IF2} may comprise a plurality of frequencies including a base frequency f_{IF} and interfering signals at various frequencies, for example, 3f_{IF}, 5f_{IF}, 7f_{IF}, 9f_{IF}, 17f_{IF}, 31f_{IF}. The LO signals S_{LO1} and S_{LO1} may also comprise a plurality of frequencies, for example, a base frequency f_{IF} and odd harmonics of the base frequency f_{IF}. For the base frequency of f_{IF}, the third harmonic frequency may be 3f_{IF}, the fifth harmonic frequency may be 5f_{IF}, the seventh harmonic frequency may be 7f_{IF}, etc. Therefore, the output signal S_{BB} may comprise a plurality of frequencies due to mixing of each frequency of the IF signal S_{IF} with each frequency of the LO signal S_{LO}, in which a DC baseband signal of the output signal S_{BB}′ may be desired to be further processed.

Since mixing of the IF signal S_{IF} with the base frequency f_{IF} of the LO signal S_{LO} may be represented as S_{BB}=cos(2π(f_{IF}−f_{LO})t), the frequencies generated may be f_{IF}−f_{IF}=0 or DC, 4f_{IF}, 6f_{IF}, etc. However, when the harmonics of the LO signal S_{LO} are considered, the additional phase differences must be taken in to account. Since the frequency of the third harmonic of the LO signal S_{LO} is tripled, the phase difference of the third harmonic is also tripled with respect to the base frequency of the LO signal S_{LO}. Therefore, the third harmonic may be described by
sin(2π(3f_{IF}t)+π)=−sin(2π(3f_{IF}t)).
The addition of π, which is equivalent to 180°, is because the third harmonic has a phase difference of 270° versus the phase difference of 90° for the base frequency. The third harmonic has an extra phase difference of 180°. Therefore, the equation describing the sum of the outputs of the two mixers may then be
S_{BB}=cos(2πf_{IF}t)cos(2πf_{LO}t)−sin(2πf_{IF}t)sin(2πf_{LO}t)=cos(2π(f_{IF}+f_{LO})t)
The frequencies generated due to the third harmonic of the LO signal S_{LO} may be a sum of the two frequencies of the IF signal S_{IF} and the LO signal S_{LO}. Similarly, the fifth harmonic of the LO signal S_{LO} may be subtracted from the frequencies of the IF signal S_{IF}, the seventh harmonic of the LO signal S_{LO} may be added to the frequencies of the IF signal S_{IF}, etc.

Therefore, the IF signal S_{IF} mixed with the harmonic frequencies (1f_{IF}, 3f_{IF}, 5f_{IF}, 7f_{IF} . . . ) of the LO signal S_{LO} may be DC, 4f_{IF}, 4f_{IF}, 8f_{IF}, etc. The interference/blocker at signal 3*S_{IF} mixed with the harmonic frequencies (1f_{IF}, 3f_{IF}, 5f_{IF}, 7f_{IF} . . . ) of the LO signal S_{LO} may be 2f_{IF}, 6f_{IF}, −2f_{IF}, 10f_{IF} etc. The interference/blocker at signal 5*S_{IF} mixed with the harmonic frequencies (1f_{IF}, 3f_{IF}, 5f_{IF}, 7f_{IF} . . . ) of the LO signal S_{LO} may be 4f_{IF}, 8f_{IF}, DC, 12f_{IF} etc. Accordingly, where there may be at least one DC component in the output signal S_{BB} from each odd harmonic of the LO signal S_{LO} in the single mixer implementation, only every other odd harmonic of the LO signal S_{LO} may contribute a DC component to the output signal S_{BB}. Therefore, the interfering components at the DC baseband that may distort the information in the output baseband signal S_{BB}′ may have been reduced by half.

FIG. 1F is a block diagram illustrating an alternate exemplary single sideband mixing circuit, in accordance with an embodiment of the invention. Referring to FIG. 1F, there is shown two mixers 190 and 192 that may comprise suitable logic, circuitry and/or code that may be adapted mix two input signals and output a signal that may comprise frequencies that may be represented as a sum and a difference of frequencies of the two signals.

An IF signal S_{IF1} may be communicated to a first of the two inputs of the mixer 190, and a local oscillator (LO) signal S_{LO1} may be communicated to a second of the two inputs of the mixer 190. An IF signal S_{IF2} that may be 90° out of phase with the IF signal S_{IF1} may be communicated to a first of the two inputs of the mixer 192, and a local oscillator (LO) signal S_{LO2} that may be 90° out of phase with the local oscillator (LO) signal S_{LO1} may be communicated to a second of the two inputs of the mixer 192. The outputs of the mixers 190 and 192 may be coupled and added together by the adder block 194 to form the output signal S_{BB}, in which an output baseband signal S_{BB}′ may be the desired component.

The IF signals S_{IF1} and S_{IF2} and the LO signals S_{LO1} and S_{LO2} may be represented by using sine and cosine notations to represent the two signals, and mixing the two signals may be represented by multiplying the two signals. As an alternative to FIG. 1E, however, the IF signal S_{IF1} may be represented by a sine function
S_{IF1}=sin(2πf_{IF}t)
and since the IF signal S_{IF2} may be 90° (or π/2 radians) out of phase with the IF signal S_{IF1} the IF signal may be represented as
S_{IF2}=sin(2πf_{IF}t+π/2)=cos(2πf_{IF}t).
The LO signals S_{LO1} and S_{LO2} may be represented as in FIG. 1E
S_{LO1}=cos(2πf_{LO}t)
S_{LO2}=cos(2πf_{LO}t−π/2)=sin(2πf_{LO}t).
The outputs of the mixers 190 and 192 may then be sin(2πf_{IF}t)cos(2πf_{LO}t) and cos(2πf_{IF}t)sin(2πf_{LO}t), respectively. Therefore, the output of the mixer 190 may be added to the negative output of the mixer 192 and the result may be represented as
S_{BB}=sin(2π_{IF}t)cos(2πf_{LO}t)−cos(2πf_{IF}t)sin(2πf_{LO}t)=sin(2π(f_{IF}−f_{LO})t)

When the positive output of the mixer 190 is added to the negative output of the mixer 192, the result may be that only one sideband is generated, rather than two sidebands that are generated from the output of one mixer. Therefore, similarly as illustrated in FIG. 1F, only every other odd harmonic of the LO signal S_{LO} may contribute a DC component to the output signal S_{BB}. This may result in the number of interfering components at the DC baseband, which may distort the information in the output baseband signal S_{BB}′, being reduced by half.

FIG. 1G is a timing diagram illustrating exemplary local oscillator signals out of phase by 90° with each other, in accordance with an embodiment of the invention. Referring to FIG. 1G, there is shown local oscillator (LO) signals S_{LO1} 196 and S_{LO2} 198. LO signal S_{LO1} 196 may be a waveform in which there may be two states—a high state and a low state. The high state may represent logic 1 and the low state may represent logic 0, for example. The LO signal S_{LO2} 198 may be 90° out of phase with respect to the LO signal S_{LO1} 196. One method of generating the LO signal S_{LO2} 198 may comprise delaying the LO signal S_{LO1} 196 by one clock cycle, for example, by utilizing a flip-flop, in which the clock signal to the flip-flop may have a frequency that may be four times the frequency of the LO signal S_{LO1} 196.

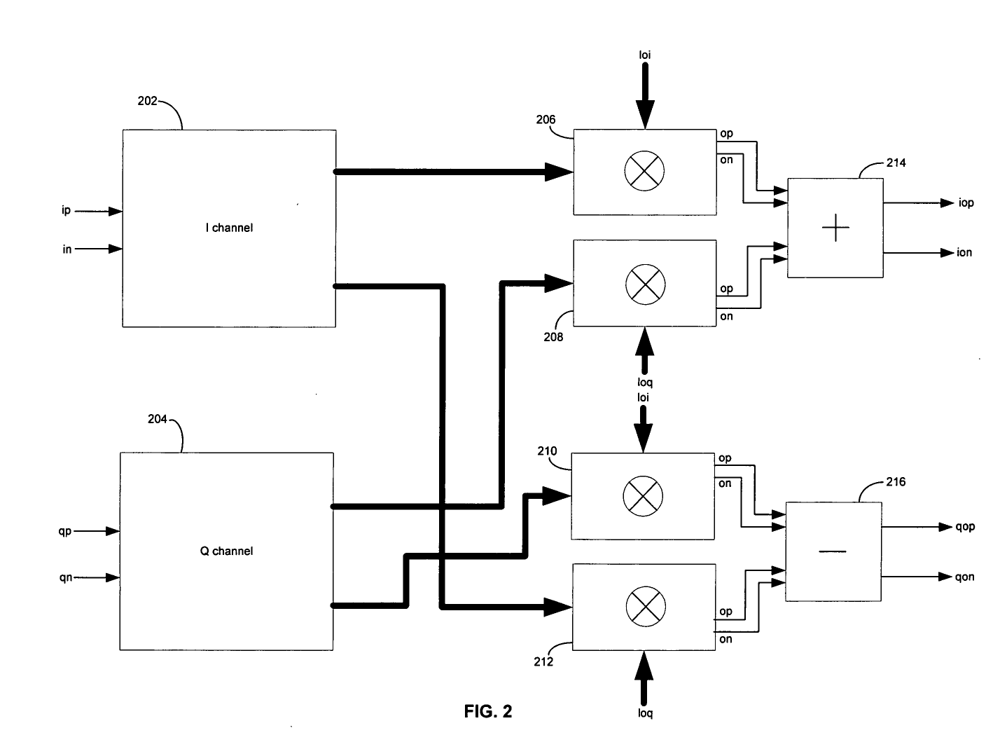

FIG. 2 is a block diagram of a receiver portion illustrating a plurality of single sideband mixing circuits, in accordance with an embodiment of the invention. Referring to FIG. 2, there is shown a I component Gm stage 202, a Q component Gm stage 204, a plurality of I component mixer circuits 206 and 212, a plurality of Q component mixer circuits 208 and 210 and a plurality of adder blocks 214 and 216.

The I component Gm stage 202 may comprise suitable logic and/or circuitry that may be adapted to receive a plurality of input signals ip and in from the output of amplifier 128 [FIG. 1] and generate a plurality of output signals to a plurality of I component mixer circuits 206 and 212. The Q component Gm stage 204 may comprise suitable logic and/or circuitry that may be adapted to receive a plurality of input signals qp and qn from the output of amplifier 138 and generate a plurality of output signals to a plurality of Q component mixer circuits 208 and 210.

The I component mixer circuit 206 may comprise suitable logic and/or circuitry that may be adapted to mix a plurality of input signals received from the I component Gm stage 202 and a plurality of polyphase local oscillator clock signals loi and generate a plurality of output signals op and on to the adder block 214. The Q component mixer circuit 208 may comprise suitable logic and/or circuitry that may be adapted to mix a plurality of input signals received from the Q component Gm stage 202 and a plurality of polyphase local oscillator clock signals loq and generate a plurality of output signals op and on to the adder block 214.

The I component mixer circuit 212 may comprise suitable logic and/or circuitry that may be adapted to mix a plurality of input signals received from the I component Gm stage 202 and a plurality of polyphase local oscillator clock signals loq and generate a plurality of output signals op and on to the adder block 216. The Q component mixer circuit 210 may comprise suitable logic and/or circuitry that may be adapted to mix a plurality of input signals received from the Q component Gm stage 202 and a plurality of polyphase local oscillator clock signals loi and generate a plurality of output signals op and on to the adder block 216.

The adder block 214 may comprise suitable logic and/or circuitry that may be adapted to add a plurality of input signals received from the I component mixer circuit 206 and the Q component mixer circuit 208 and generate a plurality of output signals iop and ion that may be an output DC signal of the I channel. The adder block 216 may comprise suitable logic and/or circuitry that may be adapted to subtract a plurality of input signals received from the I component mixer circuit 212 and the Q component mixer circuit 210 and generate a plurality of output signals qop and qon that may be an output comprising a difference signal of the Q channel.

In operation, the I component Gm stage 202 and the Q component Gm stage 204 may be adapted to receive the input signals ip and in from the output of the amplifier 128 [FIG. 1B] and qp and qn from the output of amplifier 138 [FIG. 1B] respectively and generate a plurality of output signals the plurality of I component mixer circuits 206 and 212 and a plurality of Q component mixer circuits 208 and 210. The I component mixer circuits 206 and 212 and Q component mixer circuits 208 and 210 may be adapted to mix the plurality of input signals received from the I component Gm stage 202 and the Q component Gm stage 204 with a plurality of polyphase local oscillator clock signals loi and loq and generate a plurality of output signals op and on to the adder blocks 214 and 216. The adder blocks 214 and 216 may be adapted to add a plurality of input signals received from the I component mixer circuit 206 and the Q component mixer circuit 208 and subtract a plurality of input signals received from the I component mixer circuit 212 and the Q component mixer circuit 210 respectively and generate a plurality of output signals iop and ion that may be an output differential DC signal of the I channel and generate a plurality of output signals qop and qon that may be a differential output comprising a difference signal of the Q channel respectively.

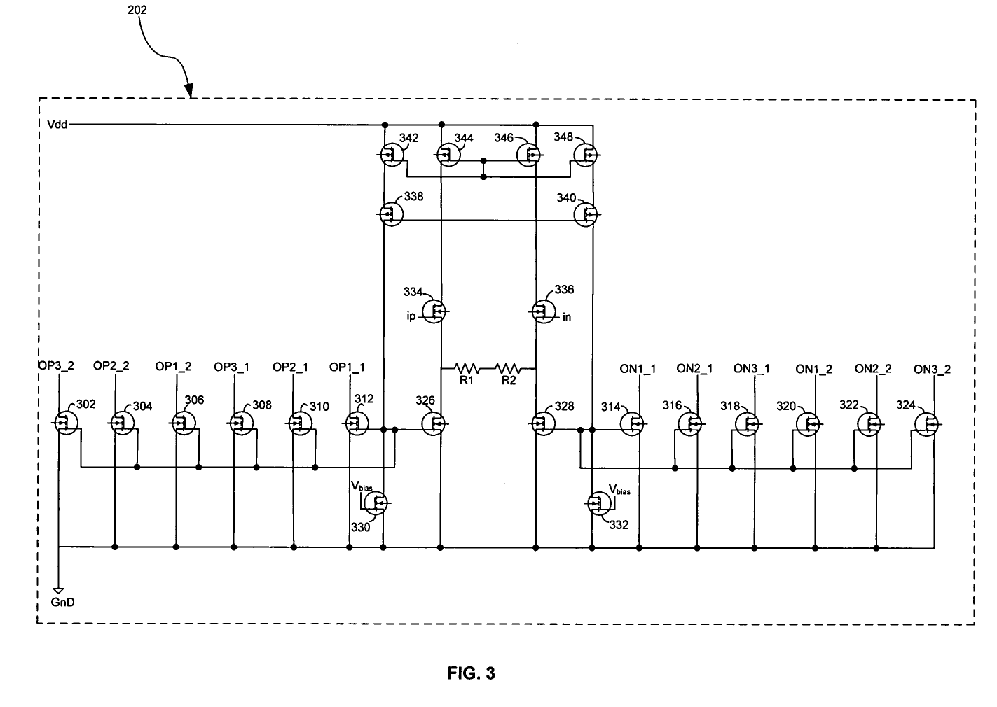

FIG. 3 is a circuit diagram of an exemplary I component Gm stage, in accordance with an embodiment of the invention. Referring to FIG. 3, there is shown the I component Gm stage 202 that comprises a plurality of NMOS transistors 302, 304, 306, 308, 310, 312, 314, 316, 318, 320, 322, 324, 326, 328, 330, 332, 334, 336, 338, 340, 342, 344, 346 and 348 and resistors R1 and R2.

The gates of the plurality of NMOS transistors 302, 304, 306, 308, 310 and 312 may be coupled to the gate of the NMOS transistor 326. The sources of the plurality of NMOS transistors 302, 304, 306, 308, 310 and 312 may be coupled to the ground GND. The drains of the plurality of NMOS transistors 302, 304, 306, 308, 310 and 312 may output a plurality of output signals OP3_2, OP2_2, OP1_2, OP3_1, OP2_1 and OP1_1 respectively to the I component mixer circuits 206 and 212. Similarly, the gates of the plurality of NMOS transistors 314, 316, 318, 320, 322 and 324 may be coupled to the gate of the NMOS transistor 328. The sources of the plurality of NMOS transistors 314, 316, 318, 320, 322 and 324 may be coupled to the ground GND. The drains of the plurality of NMOS transistors 314, 316, 318, 320, 322 and 324 may output a plurality of output signals ON1_1, ON2_1, ON3_1, ON1_2, ON2_2 and ON3_2 respectively to the I component mixer circuits 206 and 212. The sources of the NMOS transistors 326, 328, 330 and 332 may be coupled to the ground GND.

The drains of the NMOS transistors 326 and 328 may be coupled to the sources of the NMOS transistors 334 and 336 respectively. The gates of the NMOS transistors 334 and 336 may be adapted to receive the differential input signals of the I channel, ip and in respectively. The sources of the NMOS transistors 334 and 336 may be coupled to the drains of the NMOS transistors 326 and 328 respectively. The drains of the NMOS transistors 334 and 336 may be coupled to the drains of the PMOS transistors 344 and 346 respectively. The gates of the PMOS transistors 344 and 346 may be coupled to each other. The drains of the PMOS transistors 344 and 346 may be coupled to the drains of the NMOS transistors 334 and 336 respectively. The sources of the PMOS transistors 344, 346, 342 and 348 may be coupled to a supply voltage Vdd. Resistor R1 may be in series with resistor R2 and may be coupled to the drains of the NMOS transistors 326 and 328.

The gates of the PMOS transistors 342 and 348 may be coupled to each other and to the gates of the PMOS transistors 344 and 346. The drains of the PMOS transistors 342 and 348 may be coupled to the sources of the PMOS transistors 338 and 340 respectively. The gates of the PMOS transistors 338 and 340 may be coupled to each other. The sources of the PMOS transistors 338 and 340 may be coupled to the sources of the NMOS transistors 342 and 348 respectively. The sources of the NMOS transistors 338 and 340 may be coupled to the drains of the NMOS transistors 330 and 332 respectively. The gates of the NMOS transistors 330 and 332 may receive a bias voltage V_{bias}. The drains of the NMOS transistors 330 and 332 may be coupled to the drains of the PMOS transistors 338 and 340 respectively.

While the I component Gm stage 202 as described in FIG. 3 comprises NMOS transistors and is implemented utilizing a single differential amplifier stage, the invention may not be so limited. Accordingly, the I component Gm stage 202 may also comprise NMOS, PMOS and/or BJT devices and may also be implemented utilizing a plurality of differential amplifier stages.

In operation, the NMOS transistors 334 and 336 may be adapted to receive the differential input signals of the I channel from the amplifier 128 [FIG. 1b]. The differential input signals may be converted to current by the resistors R1 and R2. The NMOS transistor 326 may be configured to mirror current to the plurality of NMOS transistors 302, 304, 306, 308, 310 and 312. The current passing from resistors R1 380 and R2 382 to the drain of the NMOS transistor 326 may be mirrored to each of the NMOS transistors 302, 304, 306, 308, 310 and 312. Similarly, the NMOS transistor 328 may behave as a current mirror to the plurality of NMOS transistors 314, 316, 318, 320, 322 and 324.

Current from resistors R1 380 and R2 382 to the drain of the NMOS transistor 328 may be mirrored to each of the NMOS transistors 314, 316, 318, 320, 322 and 324. The drains of the plurality of NMOS transistors 302, 304, 306, 308, 310 and 312 may output a plurality of output signals OP3_2, OP2_2, OP1_2, OP3_1, OP2_1 and OP1_1 respectively. The drains of the plurality of NMOS transistors 314, 316, 318, 320, 322 and 324 may output a plurality of output signals ON1_1, ON2_1, ON3_1, ON1_2, ON2_2 and ON3_2 respectively. The differential pairs of output signals OP1_1 and ON1_1, OP2_1 and ON2_1, OP3_1 and ON3_1 may be received by the I component mixer circuit 206. Similarly, the differential pairs of output signals OP1_2 and ON1_2, OP2_2 and ON2_2, OP3_2 and ON3_2 may be received by the I component mixer circuit 212. Similarly, the Q component Gm stage 204 may comprise suitable logic and/or circuitry that may be adapted to generate a plurality of differential pairs of output signals, for example, six differential pairs of output signals to the Q component mixer circuits 208 and 210 respectively.

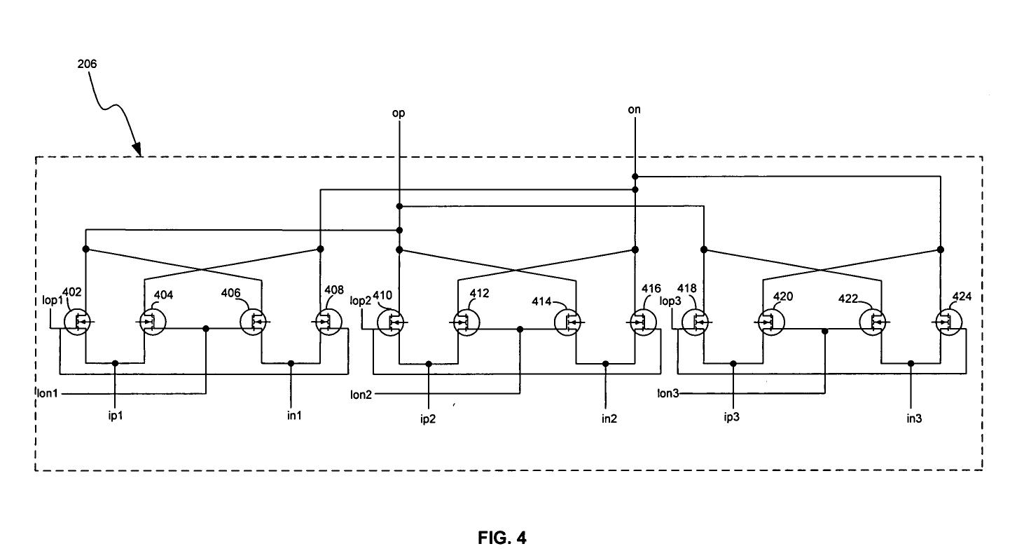

FIG. 4 is a circuit diagram of an exemplary I component mixer circuit, in accordance with an embodiment of the invention. Referring to FIG. 4, there is shown the I component mixer circuit 206 that comprises a plurality of NMOS transistors 402, 404, 406, 408, 410, 412, 414, 416, 418, 420, 422 and 424.

The gates of the NMOS transistors 402 and 408 may be adapted to receive a first positive component of a polyphase local oscillator clock signal lop1 and the gates of the NMOS transistors 404 and 406 may receive a first negative component of a polyphase local oscillator clock signal lon1. The sources of the NMOS transistors 402 and 404 may be adapted to receive a first positive component of an input signal ip1 and the sources of the NMOS transistors 406 and 408 may receive a first negative component of an input signal in1. The first positive and negative components of the input signal ip1 and in1 may be received from the I component Gm stage 202, for example, the differential pair of output signals OP1_1 and ON1_1 may be the first positive and negative components of the input signal ip1 and in1 respectively. The drains of the NMOS transistors 402 and 406 may be coupled to the drain of the NMOS transistor 410. The drains of the NMOS transistors 404 and 408 may be coupled to the drain of the NMOS transistor 416.

The gates of the NMOS transistors 410 and 416 may receive a second positive component of a polyphase local oscillator clock signal lop2 and the gates of the NMOS transistors 412 and 414 may receive a second negative component of a polyphase local oscillator clock signal lon2. The sources of the NMOS transistors 410 and 412 may receive a second positive component of an input signal ip2 and the sources of the NMOS transistors 414 and 416 may receive a second negative component of an input signal in2. The second positive and negative components of the input signal ip2 and in2 may be received from the I component Gm stage 202, for example, the differential pair of output signals OP2_1 and ON2_1 may be the second positive and negative components of the input signal ip2 and in2 respectively. The drains of the NMOS transistors 410 and 414 may be coupled together and may generate a positive component of an output signal op to the adder block 214 [FIG. 2]. The drains of the NMOS transistors 412 and 416 may be coupled together and may generate a negative component of an output signal on to the adder block 214.

Similarly, the gates of the NMOS transistors 418 and 424 may receive a third positive component of a polyphase local oscillator clock signal lop3 and the gates of the NMOS transistors 420 and 422 may receive a third negative component of a polyphase local oscillator clock signal lon3. The sources of the NMOS transistors 418 and 420 may receive a third positive component of an input signal ip3 and the sources of the NMOS transistors 422 and 424 may receive a third negative component of an input signal in3. The third positive and negative components of the input signal ip3 and in3 may be received from the I component Gm stage 202, for example, the differential pair of output signals OP3_1 and ON3_1 may be the third positive and negative components of the input signal ip3 and in3 respectively. The drains of the NMOS transistors 418 and 422 may be coupled to the drain of the NMOS transistor 410. The drains of the NMOS transistors 420 and 424 may be coupled to the drain of the NMOS transistor 416.

While the I component mixer circuit 206 as described in FIG. 4 comprises NMOS transistors and is implemented utilizing a plurality of mixer stages, the invention may not be so limited. Accordingly, the I component mixer circuit 206 may also comprise PMOS and/or MOS devices.

The I component mixer circuits 206 and 212 [FIG. 2] may each comprise a plurality of Gilbert cells, for example, three Gilbert cells in parallel and generate a differential output signal op and on by adding the outputs of the individual Gilbert cells. Similarly, the Q component mixer circuits 208 and 210 may each comprise a plurality of Gilbert cells, for example, three Gilbert cells in parallel and generate a differential output signal op and on by adding the outputs of the individual Gilbert cells.

A plurality of Gm stages, for example, 12 Gm stages may be required to mix a plurality of polyphase clock signals with the output signals from the differential amplifiers that may increase current consumption. By utilizing the above described method and system for sharing the Gm stage of the second IF mixer utilizing polyphase local oscillator clock signals, a significant reduction in current consumption may be achieved.

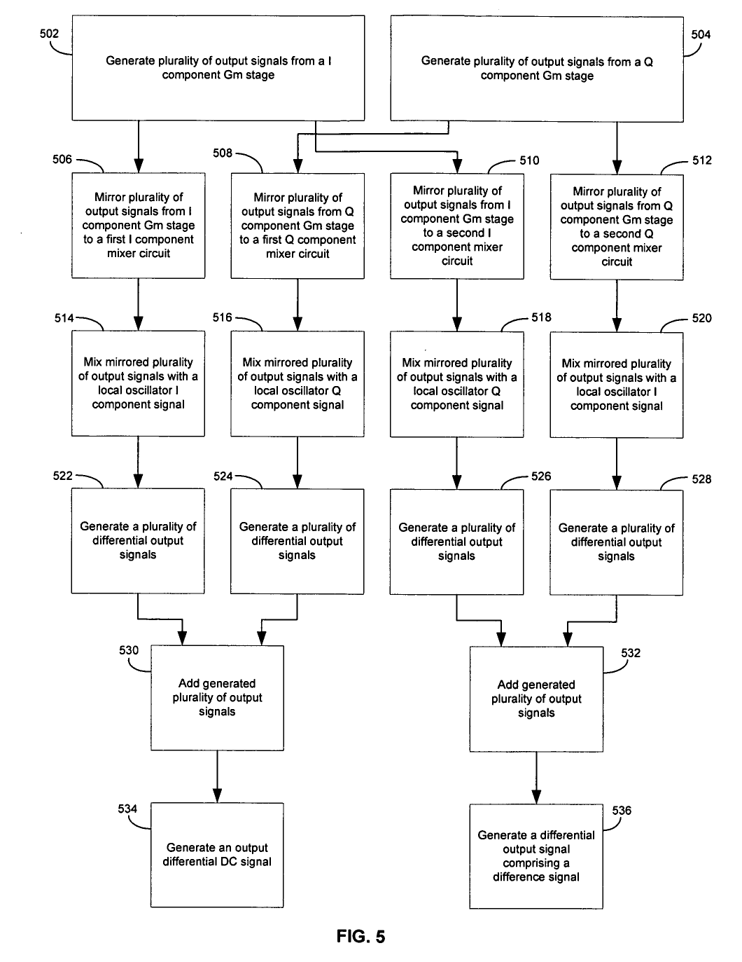

FIG. 5 is a flowchart illustrating exemplary steps to generate a differential output DC signal, in accordance with an embodiment of the invention. Referring to FIG. 5, there is shown, in step 502, a plurality of output signals may be generated from a I component Gm stage, for example, the I component Gm stage 202 [FIG. 2]. In step 504, a plurality of output signals may be generated from a Q component Gm stage, for example, the Q component Gm stage 204. In steps 506 and 510, the generated plurality of output signals from the I component Gm stage may be mirrored to a first I component mixer circuit, for example, the I component mixer circuit 206 and a second I component mixer circuit, for example, the I component mixer circuit 212 respectively. Similarly, in steps 506 and 510, the generated plurality of output signals from the Q component Gm stage may be mirrored to a first Q component mixer circuit, for example, the Q component mixer circuit 208 and a second Q component mixer circuit, for example, the Q component mixer circuit 210 respectively.

In steps 514 and 516, the mirrored plurality of output signals from 1 component mixer circuit and Q component mixer circuit respectively may be mixed with a local oscillator I component signal and a local oscillator Q component signal respectively. In steps 518 and 520, the mirrored plurality of output signals from 1 component mixer circuit and Q component mixer circuit respectively may be mixed with a local oscillator Q component signal and a local oscillator I component signal respectively. In steps 522 and 524, a plurality of differential output signals may be generated in response to mixing the mirrored plurality of output signals with a I component signal and a Q component signal respectively. In steps 526 and 528, a plurality of differential output signals may be generated in response to mixing the mirrored plurality of output signals with a Q component signal and a I component signal respectively. In step 530, the generated plurality of output signals from step 522 and 524 may be added and in step 534 a differential DC output signal may be generated in response to the adding step 530. In step 532, the generated plurality of output signals from step 526 and 528 may be added and in step 536 a differential DC output signal may be generated in response to the adding step 532.

In accordance with an embodiment of the invention, a system for improving signal quality in a receiver may be provided. With reference to FIG. 2, the system may comprise a I component Gm stage 202 [FIG. 2] and a Q component Gm stage 204 that may comprise suitable logic and/or circuitry that may be adapted to generate a plurality of output signals from a single I component Gm stage and a single Q component Gm stage. Current generated from the plurality of output signals from the I component Gm stage 202 may be mirrored to a first I component mixer circuit 206 and a second I component mixer circuit 212, and from the Q component Gm stage 204 to a first Q component mixer circuit 208 and a second Q component mixer circuit 210. An output DC signal from an output of the first I component mixer circuit 206 and the first Q component may be generated from the mixer circuit 208. The system may be adapted to generate an output that may comprise a difference signal from the second I component mixer circuit 212 and the second Q component mixer circuit 210.

The current generated by the plurality of output signals from the I component Gm stage 202 may be mirrored to the first I component mixer circuit 206 may be defined by cos(2πf_{if}t), where f_{if} may be a base frequency of the generated plurality of output signals from the I component Gm stage 202 to the first I component mixer circuit 206. The system may comprise circuitry that may be adapted to generate a first signal by mixing the generated plurality of output signals mirrored from the I component Gm stage 202 to the first I component mixer circuit 206 with a local oscillator I component signal loi that may be defined by cos(2πfₗₒt), where fₗₒ may be a frequency of the local oscillator I component signal.

The generated plurality of output signals mirrored from the Q component Gm stage 204 to the first Q component mixer circuit 208 may be defined by sin(2πf_{if}t), where f_{if} may be a base frequency of the generated plurality of output signals mirrored from the Q component Gm stage 204 to the first Q component mixer circuit 208. The system may comprise circuitry that may be adapted to generate a second signal by mixing the generated plurality of output signals mirrored from the Q component Gm stage 204 to the first Q component mixer circuit 208 with a local oscillator Q component signal loq that may be defined by sin(2πfₗₒt), where fₗₒ may be a frequency of the local oscillator Q component signal. Circuitry may be adapted to add the generated first signal and the generated second signal to generate the output differential DC signal iop and ion.

The generated plurality of output signals mirrored from the I component Gm stage 202 to the second I component mixer circuit 212 may be defined by cos(2πf_{if}t), where f_{if} may be a base frequency of the generated plurality of output signals from the I component Gm stage 202 to the second I component mixer circuit 212. The system may be adapted to generate a third signal by mixing the generated plurality of output signals mirrored from the I component Gm stage 202 to the second I component mixer circuit 212 with a local oscillator Q component signal loq that may be defined by sin(2πfₗₒt), where fₗₒ may be a frequency of the local oscillator Q component signal.

The generated plurality of output signals mirrored from the Q component Gm stage 204 to the second Q component mixer circuit 210 may be defined by sin(2πf_{if}t), where f_{if} may be a base frequency of the generated plurality of output signals mirrored from the Q component Gm stage 204 to the second Q component mixer circuit 210. The system may comprise circuitry that may be adapted to generate a fourth signal may be generated by mixing the generated plurality of output signals mirrored from the Q component Gm stage 204 to the second Q component mixer circuit 210 with a local oscillator I component signal loi that may be defined by cos(2πfₗₒt), where fₗₒ may be a frequency of the local oscillator I component signal. Circuitry may be adapted to add the generated third signal and the generated fourth signal to generate the differential output qop and qon that may comprise the difference signal.

Accordingly, the present invention may be realized in hardware, software, or a combination of hardware and software. The present invention may be realized in a centralized fashion in at least one computer system, or in a distributed fashion where different elements are spread across several interconnected computer systems. Any kind of computer system or other apparatus adapted for carrying out the methods described herein is suited. A typical combination of hardware and software may be a general-purpose computer system with a computer program that, when being loaded and executed, controls the computer system such that it carries out the methods described herein.

The present invention may also be embedded in a computer program product, which comprises all the features enabling the implementation of the methods described herein, and which when loaded in a computer system is able to carry out these methods. Computer program in the present context means any expression, in any language, code or notation, of a set of instructions intended to cause a system having an information processing capability to perform a particular function either directly or after either or both of the following: a) conversion to another language, code or notation; b) reproduction in a different material form.

While the present invention has been described with reference to certain embodiments, it will be understood by those skilled in the art that various changes may be made and equivalents may be substituted without departing from the scope of the present invention. In addition, many modifications may be made to adapt a particular situation or material to the teachings of the present invention without departing from its scope. Therefore, it is intended that the present invention not be limited to the particular embodiment disclosed, but that the present invention will include all embodiments falling within the scope of the appended claims.

What is claimed is:

1. A method for improving signal quality in a receiver, the method comprising:
generating a plurality of output signals from a single I component Gm stage and a single Q component Gm stage;
mirroring said generated plurality of output signals from said I component Gm stage to at least a first I component mixer circuit and at least a second I component mixer circuit, and from said Q component Gm stage to at least a first Q component mixer circuit and at least a second Q component mixer circuit;
generating an output DC signal from an output of said first I component mixer circuit and said first Q component mixer circuit; and
generating an output comprising a difference signal from said second I component mixer circuit and said second Q component mixer circuit.

2. The method according to claim 1, wherein said generated plurality of output signals mirrored from said I component Gm stage to said first I component mixer circuit is defined by cos(2πf_{if}t), where f_{if} is a base frequency of said generated plurality of output signals from said I component Gm stage to said first I component mixer circuit.

3. The method according to claim 2, further comprising generating at least a first signal by mixing said generated plurality of output signals mirrored from said I component Gm stage to said first I component mixer circuit with a local oscillator I component signal defined by cos(2πfₗₒt), where fₗₒ is a frequency of said local oscillator I component signal.

4. The method according to claim 3, wherein said generated plurality of output signals mirrored from said Q component Gm stage to said first Q component mixer circuit is defined by sin(2πf_{if}t), where f_{if} is a base frequency of said generated plurality of output signals mirrored from said Q component Gm stage to said first Q component mixer circuit.

5. The method according to claim 4, further comprising generating at least a second signal by mixing said generated plurality of output signals mirrored from said Q component Gm stage to said first Q component mixer circuit with a local oscillator Q component signal defined by sin(2πfₗₒt), where fₗₒ is a frequency of said local oscillator Q component signal.

6. The method according to claim 5, further comprising adding said generated first signal and said generated second signal to generate said output DC signal.

7. The method according to claim 1, wherein said generated plurality of output signals mirrored from said I component Gm stage to said second I component mixer circuit is defined by cos(2πf_{if}t), where f_{if} is a base frequency of said generated plurality of output signals from said I component Gm stage to said second I component mixer circuit.

8. The method according to claim 7, further comprising generating at least a third signal by mixing said generated plurality of output signals mirrored from said I component Gm stage to said second I component mixer circuit with a local oscillator Q component signal defined by sin(2πfₗₒt), where fₗₒ is a frequency of said local oscillator Q component signal.

9. The method according to claim 8, wherein said generated plurality of output signals mirrored from said Q component Gm stage to said second Q component mixer circuit is defined by sin(2πf_{if}t), where f_{if} is a base frequency of said generated plurality of output signals mirrored from said Q component Gm stage to said second Q component mixer circuit.

10. The method according to claim 9, further comprising generating at least a fourth signal by mixing said generated plurality of output signals mirrored from said Q component Gm stage to said second Q component mixer circuit with a local oscillator I component signal defined by cos(2πfₗₒt), where fₗₒ is a frequency of said local oscillator I component signal.

11. The method according to claim 10, further comprising adding said generated third signal and said generated fourth signal to generate said output comprising said difference signal.

12. A system for improving signal quality in a receiver, the system comprising:
circuitry that generates a plurality of output signals from a single I component Gm stage and a single Q component Gm stage;
circuitry that mirrors said generated plurality of output signals from said I component Gm stage to at least a first I component mixer circuit and at least a second I component mixer circuit, and from said Q component Gm stage to at least a first Q component mixer circuit and at least a second Q component mixer circuit;
circuitry that generates an output DC signal from an output of said first I component mixer circuit and said first Q component mixer circuit; and
circuitry that generates an output comprising a difference signal from said second I component mixer circuit and said second Q component mixer circuit.

13. The system according to claim 12, wherein said generated plurality of output signals mirrored from said I component Gm stage to said first I component mixer circuit is defined by cos(2πf_{if}t), where f_{if} is a base frequency of said generated plurality of output signals from said I component Gm stage to said first I component mixer circuit.

14. The system according to claim 13, further comprising circuitry that generates at least a first signal by mixing said generated plurality of output signals mirrored from said I component Gm stage to said first I component mixer circuit with a local oscillator I component signal defined by cos(2πfₗₒt), where fₗₒ is a frequency of said local oscillator I component signal.

15. The system according to claim 14, wherein said generated plurality of output signals mirrored from said Q component Gm stage to said first Q component mixer circuit is defined by sin(2πf_{if}t), where f_{if} is a base frequency of said generated plurality of output signals mirrored from said Q component Gm stage to said first Q component mixer circuit.

16. The system according to claim 15, further comprising circuitry that generates at least a second signal by mixing said generated plurality of output signals mirrored from said Q component Gm stage to said first Q component mixer circuit with a local oscillator Q component signal defined by sin(2πfₗₒt), where fₗₒ is a frequency of said local oscillator Q component signal.

17. The system according to claim 16, further comprising circuitry that adds said generated first signal and said generated second signal to generate said output DC signal.

18. The system according to claim 12, wherein said generated plurality of output signals mirrored from said I component Gm stage to said second I component mixer circuit is defined by cos(2πf_{if}t), where f_{if} is a base frequency of said generated plurality of output signals from said I component Gm stage to said second I component mixer circuit.

19. The system according to claim 18, further comprising circuitry that generates at least a third signal by mixing said generated plurality of output signals mirrored from said I component Gm stage to said second I component mixer circuit with a local oscillator Q component signal defined by sin(2πfₗₒt), where fₗₒ is a frequency of said local oscillator Q component signal.

20. The system according to claim 19, wherein said generated plurality of output signals mirrored from said Q component Gm stage to said second Q component mixer circuit is defined by sin(2πf_{if}t), where f_{if} is a base frequency of said generated plurality of output signals mirrored from said Q component Gm stage to said second Q component mixer circuit.

21. The system according to claim 20, further comprising circuitry that generates at least a fourth signal by mixing said generated plurality of output signals mirrored from said Q component Gm stage to said second Q component mixer circuit with a local oscillator I component signal defined by cos(2πfₗₒt), where fₗₒ is a frequency of said local oscillator I component signal.

22. The system according to claim 21, further comprising circuitry that adds said generated third signal and said generated fourth signal to generate said output comprising said difference signal.
